(19) United States
(12) Patent Application Publication
(10) Pub. No.: US 2026/0173613 A1
(43) Pub. Date: Jun. 18, 2026

(54) DISPLAY DEVICE, LIGHT-EMITTING DEVICE PACKAGE AND METHOD OF MANUFACTURING LIGHT-EMITTING DEVICE PACKAGE

(71) Applicant: LG Display Co., Ltd., Seoul (KR)

(72) Inventors: Chan KIM, Paju-si (KR); JaeHoon Jang, Paju-si (KR); JoonKwon Moon, Paju-si (KR); Jaekyung Shin, Paju-si (KR)

(73) Assignee: LG Display Co., Ltd., Seoul (KR)

(21) Appl. No.: 19/330,613

(22) Filed: Sep. 16, 2025

(30) Foreign Application Priority Data
Dec. 18, 2024 (KR) 10-2024-0189464

(51) Int. Cl. H10H 29/39; H10H 29/01

(52) U.S. Cl. CPC H10H 29/39; H10H 29/012

(57) ABSTRACT

A display device, a light-emitting device package, and a method of manufacturing the light-emitting device package are discussed. The light-emitting device package can include a package substrate, a first light-emitting device disposed on the package substrate, a second light-emitting device disposed on the package substrate, a first anchor penetrating through the package substrate, and a second anchor penetrating through the package substrate.

### CROSS-REFERENCE TO RELATED APPLICATION

This application claims priority to Korean Patent Application No. 10-2024-0189464, filed in the Republic of Korea on December 18, 2024, which is hereby incorporated by reference for all purposes as if fully set forth herein.

### BACKGROUND

### Field

The embodiments of the present disclosure relate to a display device, a light-emitting device package, and a method of manufacturing the light-emitting device package.

### Discussion of the Related Art

As the information society advances, the demand for display devices for displaying images is increasing in various forms. Recently, various display devices, such as liquid crystal display (LCD) devices and organic light-emitting display (OLED) devices, have been widely utilized.

A plurality of light-emitting devices can be arranged on a display panel. The plurality of light-emitting devices can be transferred onto a substrate through a stamping process. In this case, the light-emitting devices can be transferred one by one. However, when the plurality of light-emitting devices are mounted on a single package substrate, they can form a light-emitting device package, and the light-emitting device package can also be transferred onto the substrate.

### SUMMARY OF THE DISCLOSURE

The embodiments of the present disclosure can provide a display device, a light-emitting device package, and a method of manufacturing the light-emitting device package, which can minimize wiring space in the light-emitting device package through a plurality of anchors positioned on the package substrate.

The embodiments of the present disclosure can provide a display device, a light-emitting device package, and a method of manufacturing the light-emitting device package, which can enable a high-density arrangement of light-emitting devices by minimizing wiring space in the light-emitting device package.

The embodiments of the present disclosure can provide a display device, a light-emitting device package, and a method of manufacturing the light-emitting device package, which can facilitate lighting inspection of the light-emitting devices by manufacturing the light-emitting device package on an inspection wafer.

The embodiments of the present disclosure can provide a display device, a light-emitting device package, and a method of manufacturing the light-emitting device package, which can optimize the manufacturing process by enabling the formation of a high-density light-emitting device package while facilitating lighting inspection of the light-emitting devices.

The objects of the embodiments of the present disclosure are not limited to the objects mentioned herein, and other objects that are not explicitly stated can be clearly understood by those skilled in the art from the following descriptions.

The embodiments of the present disclosure can provide a display device comprising a lower substrate; a plurality of connection electrodes disposed on the lower substrate; a package substrate disposed on the plurality of connection electrodes; a first light-emitting device disposed on the package substrate, including a first light-emitting layer, and a first electrode and a second electrode positioned below the first light-emitting layer; a second light-emitting device disposed on the package substrate, including a second light-emitting layer, and a third electrode and a fourth electrode positioned below the second light-emitting layer; a first anchor electrically connected to the first electrode and a first connection electrode of the plurality of connection electrodes, penetrating through the package substrate, and overlapping with the first electrode and the first connection electrode; a second anchor electrically connected to the second electrode and a second connection electrode of the plurality of connection electrodes, penetrating through the package substrate, and overlapping with the second electrode and the second connection electrode; a third anchor electrically connected to the third electrode and a third connection electrode of the plurality of connection electrodes, penetrating through the package substrate, and overlapping with the third electrode and the third connection electrode; and a fourth anchor electrically connected to the fourth electrode and a fourth connection electrode of the plurality of connection electrodes, penetrating through the package substrate, and overlapping with the fourth electrode and the fourth connection electrode.

The embodiments of the present disclosure can provide a light-emitting device package comprising a package substrate; a first light-emitting device disposed on the package substrate, including a first light-emitting layer, a first electrode electrically connected to the first light-emitting layer, and a second electrode electrically connected to the first light-emitting layer; a second light-emitting device disposed on the package substrate, including a second light-emitting layer, a third electrode electrically connected to the second light-emitting layer, and a fourth electrode electrically connected to the second light-emitting layer; a first anchor electrically connected to the first electrode, overlapping with the first electrode, and penetrating through the package substrate; and a second anchor electrically connected to the third electrode, overlapping with the third electrode, and penetrating through the package substrate.

The embodiments of the present disclosure can provide a method of manufacturing a light-emitting device package, comprising a filling step of filling a conductive paste into a plurality of anchor holes of a package substrate; a light-emitting device placement step of placing a plurality of light-emitting devices on the conductive paste; a thermo-compression step of applying heat and external force to the plurality of light-emitting devices, thereby converting the conductive paste into a plurality of anchor posts; and a lighting inspection step of supplying power to the plurality of anchor posts through probe electrodes on a wafer substrate and inspecting whether the plurality of light-emitting devices emit light.

According to the embodiments of the present disclosure, a display device, a light-emitting device package, and a method of manufacturing the light-emitting device package can be provided, which can minimize wiring space in the light-emitting device package through a plurality of anchors positioned on the package substrate.

According to the embodiments of the present disclosure, a display device, a light-emitting device package, and a method of manufacturing the light-emitting device package can be provided, which can enable a high-density arrangement of light-emitting devices by minimizing wiring space in the light-emitting device package.

According to the embodiments of the present disclosure, a display device, a light-emitting device package, and a method of manufacturing the light-emitting device package can be provided, which can facilitate lighting inspection of the light-emitting devices by manufacturing the light-emitting device package on an inspection wafer.

According to the embodiments of the present disclosure, a display device, a light-emitting device package, and a method of manufacturing the light-emitting device package can be provided, which can optimize the manufacturing process by enabling the formation of a high-density light-emitting device package while facilitating lighting inspection of the light-emitting devices.

The effects of the embodiments of the present disclosure are not limited to the effects mentioned above, and other effects that are not explicitly stated will be clearly understood by those skilled in the art from the descriptions of the claims.

### BRIEF DESCRIPTION OF THE DRAWINGS

The present disclosure will be more fully understood from the following detailed description and the accompanying drawings. The detailed description and drawings are provided for illustrative purposes only and are not intended to limit the scope of the present disclosure.

FIG. 1 is a system configuration diagram of a display device according to the embodiments of the present disclosure.

FIG. 2 is a diagram illustrating a subpixel according to the embodiments of the present disclosure.

FIG. 3 is a diagram of a plurality of light-emitting device packages arranged on a display panel according to the embodiments of the present disclosure.

FIG. 4 is a cross-sectional view of the A-B region of the light-emitting device package shown in FIG. 3.

FIGS. 5 to 8 are diagrams illustrating a process of transferring a light-emitting device package onto a lower substrate according to the embodiments of the present disclosure.

FIGS. 9 and 10 are diagrams illustrating a process of transferring a light-emitting device package onto a lower substrate according to the embodiments of the present disclosure.

FIGS. 11 and 12 are diagrams illustrating a process of transferring a light-emitting device package onto a lower substrate according to the embodiments of the present disclosure.

FIGS. 13 to 16 are diagrams illustrating a process of transferring a light-emitting device package onto a lower substrate according to the embodiments of the present disclosure.

FIG. 17 is a flowchart of a method of manufacturing a light-emitting device package according to the embodiments of the present disclosure.

### DETAILED DESCRIPTION OF THE EMBODIMENTS

In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description can make the subject matter in some embodiments of the present invention rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present invention. Each of these terms is not used to define essence, order, sequence, or number of elements etc., but is used merely to distinguish the corresponding element from other elements.

When it is mentioned that a first element "is connected or coupled to", “contacts or overlaps” etc. a second element, it should be interpreted that, not only can the first element “be directly connected or coupled to” or “directly contact or overlap” the second element, but a third element can also be "interposed" between the first and second elements, or the first and second elements can "be connected or coupled to", “contact or overlap”, etc. each other via a fourth element. Here, the second element can be included in at least one of two or more elements that "are connected or coupled to", “contact or overlap”, etc. each other.

When time relative terms, such as "after," "subsequent to," "next," "before," and the like, are used to describe processes or operations of elements or configurations, or flows or steps in operating, processing, manufacturing methods, these terms can be used to describe non-consecutive or non-sequential processes or operations unless the term "directly" or "immediately" is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may” and vice versa.

Various embodiments of the present disclosure will be described in detail with reference to the accompanying drawings. All the components of each display device and each light-emitting device package according to all embodiments of the present disclosure are operatively coupled and configured.

Hereinafter, a display device according to embodiments of the present disclosure will be described.

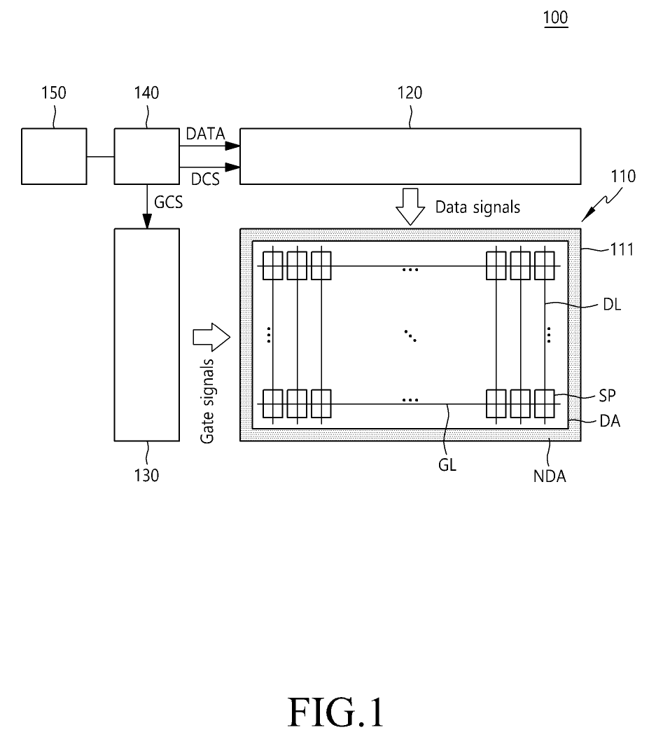

FIG. 1 is a system configuration diagram of a display device 100 according to the embodiments of the present disclosure.

Referring to FIG. 1, the display device 100 according to the embodiments of the present disclosure can include a display panel 110 and a display driving circuit as components for image display. The display driving circuit can include a data driver circuit 120, a gate driver circuit 130, and a display controller 140 to drive the display panel 110.

The display panel 110 can include a substrate 111 and a plurality of subpixels SP disposed on the substrate 111.

The substrate 111 of the display panel 110 can include a display area DA, where images can be displayed, and a non-display area NDA positioned outside the display area DA.

A plurality of subpixels SP for image display can be arranged in the display area DA, while the non-display area NDA can include a pad area positioned in a first direction from the display area DA.

In the display panel 110 according to the embodiments of the present disclosure, the non-display area NDA can be very small. In the present disclosure, the non-display area NDA is also referred to as a "bezel."

Various types of signal lines for driving the plurality of subpixels SP can be arranged on the substrate 111 of the display panel 110.

The display device 100 according to the embodiments of the present disclosure can be a liquid crystal display (LCD) device or a self-emitting display device in which the display panel 110 emits light by itself. When the display device 100 is a self-emitting display device, each of the plurality of subpixels SP can include a light-emitting device.

For example, the display device 100 according to the embodiments of the present disclosure can be an organic light-emitting display device in which the light-emitting device is implemented as an organic light-emitting diode (OLED). In another example, the display device 100 can be an inorganic light-emitting display device in which the light-emitting device is implemented as an inorganic light-emitting diode. In yet another example, the display device 100 can be a quantum dot display device in which the light-emitting device is implemented as a quantum dot, a semiconductor crystal that emits light.

The structure of each subpixel SP can vary depending on the type of display device 100. For example, when the display device 100 is a self-emitting display device in which each subpixel SP emits light, each subpixel SP can include a light-emitting device which self-emits light, one or more transistors, and one or more capacitors.

Various types of signal lines can include a plurality of data lines DL for transmitting data signals (also referred to as data voltages or image signals) and a plurality of gate lines GL for transmitting gate signals (also referred to as scan signals).

The data driver circuit 120 can drive the plurality of data lines DL and output data signals to the plurality of data lines DL.

The data driver circuit 120 can receive digital image data DATA from the display controller 140, convert the received image data DATA into analog data signals, and output the analog data signals to the plurality of data lines DL.

The data driver circuit 120 can be connected to one side of the display panel 110 (e.g., an upper or lower side). Alternatively, depending on the driving method or panel design, the data driver circuit 120 can be connected to both sides (e.g., both the upper and lower sides) of the display panel 110, or to two or more of the four sides of the display panel 110.

The data driver circuit 120 can be connected to the periphery of the display area DA of the display panel 110. Alternatively, the data driver circuit 120 can be disposed within the display area DA of the display panel 110.

The gate driver circuit 130 can drive the plurality of gate lines GL and output gate signals to the plurality of gate lines GL.

The gate driver circuit 130 can receive a first gate voltage corresponding to a turn-on level voltage and a second gate voltage corresponding to a turn-off level voltage, along with various gate driver control signals GCS, to generate gate signals and supply the generated gate signals to the plurality of gate lines GL.

The display controller 140 can control the data driver circuit 120 and the gate driver circuit 130, and can control the driving timing of the plurality of data lines DL and the plurality of gate lines GL.

The display controller 140 can supply a data driver control signal DCS to the data driver circuit 120 to control the data driver circuit 120 and can supply a gate driver control signal GCS to the gate driver circuit 130 to control the gate driver circuit 130.

The display controller 140 can receive input image data from a host system 150 and supply image data DATA to the data driver circuit 120 based on the input image data.

The display controller 140 can be implemented as a separate component from the data driver circuit 120 or can be integrated with the data driver circuit 120 as an integrated circuit.

The display controller 140 can be a timing controller used in related display technology. Alternatively, the display controller 140 can be a control device that includes a timing controller and performs additional control functions, or it can be a control device separate from the timing controller. In some cases, the display controller 140 can be a circuit within a control device.

The display controller 140 can be mounted on a printed circuit board (PCB) or a flexible printed circuit (FPC), and can be electrically connected to the data driver circuit 120 and the gate driver circuit 130 through the PCB or FPC.

The display device 100 according to the embodiments of the present disclosure can provide not only an image display function but also a touch sensing function. For this purpose, the display device 100 can include a touch sensor and a touch sensing circuit that detects whether a touch has occurred by a touch object such as a finger or a pen and determines the touch position.

The touch sensing circuit can include a touch driver circuit that drives the touch sensor, senses touch inputs, generates touch sensing data, and outputs the data. The touch sensing circuit can also include a touch controller that detects touch occurrences or determines touch positions based on the touch sensing data.

The touch sensor can include a plurality of touch electrodes. Additionally, the touch sensor can further include a plurality of touch lines for electrically connecting the plurality of touch electrodes to the touch driver circuit.

The touch driver circuit can supply a touch driving signal to at least one of the plurality of touch electrodes and can sense at least one of the plurality of touch electrodes to generate touch sensing data.

The touch driver circuit and the touch controller included in the touch sensing circuit can be implemented as separate devices or as a single device. Additionally, the touch driver circuit and the data driver circuit can be implemented as separate devices or as a single device.

The display device 100 can further include a power supply circuit that supplies various power sources to the display driving circuit and/or the touch sensing circuit.

The display device 100 according to the embodiments of the present disclosure can further include electronic devices such as a camera (image sensor) and a sensing sensor. For example, the sensing sensor can be a sensor that detects an object or a human body by receiving light such as infrared, ultrasonic, or ultraviolet light.

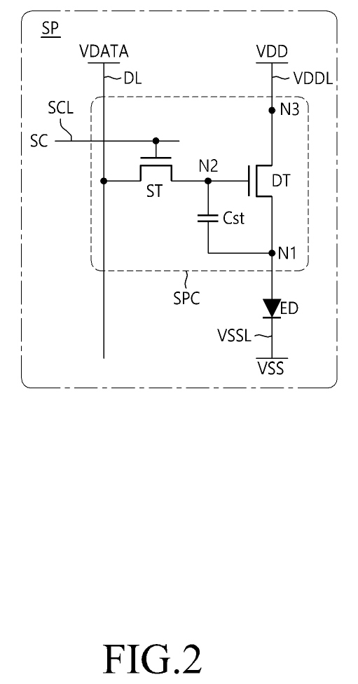

FIG. 2 is a diagram illustrating a subpixel SP according to the embodiments of the present disclosure.

Referring to FIG. 2, each of the plurality of subpixels SP of the display device (e.g., device 100) can include a light-emitting device ED and a subpixel circuit SPC for driving the light-emitting device ED.

The subpixel circuit SPC can include a plurality of pixel driving transistors for driving the light-emitting device ED and at least one capacitor. In the present disclosure, the subpixel circuit SPC can supply a driving current to the light-emitting device ED at a predetermined timing to drive the light-emitting device ED. The light-emitting device ED can emit light by being driven by the driving current.

The plurality of pixel driving transistors can include a driving transistor DT for driving the light-emitting device ED and a scan transistor ST that turns on or off in response to a scan signal SC.

The driving transistor DT can supply a driving current to the light-emitting device ED.

The scan transistor ST can be configured to control the electrical state of a corresponding node within the subpixel circuit SPC or to control the state or operation of the driving transistor DT.

At least one capacitor can include a storage capacitor Cst for maintaining a constant voltage during a frame.

To drive the subpixel SP, a data signal VDATA, which is an image signal, and a scan signal SC, which is a gate signal, can be applied to the subpixel SP. Additionally, to drive the subpixel SP, a common pixel driving voltage including a driving voltage VDD and a reference voltage VSS can be applied to the subpixel SP.

The light-emitting device ED can be an organic light-emitting diode (OLED), an inorganic light-emitting diode (LED), or a quantum dot light-emitting device. For example, when the light-emitting device ED is an organic light-emitting diode (OLED), the light-emitting device ED can include an emission layer containing an organic material.

The driving transistor DT can be a transistor for supplying a driving current to the light-emitting device ED. The driving transistor DT can be connected between a driving voltage line VDDL and the light-emitting device ED.

The driving transistor DT can include: a first node N1 electrically connected to the light-emitting device ED; a second node N2 to which a data signal VDATA can be applied; and a third node N3 to which a driving voltage VDD is applied from a driving voltage line VDDL.

In the driving transistor DT, the second node N2 can be a gate node. The first node N1 can be a source node or a drain node. The third node N3 can be a drain node or a source node. Hereinafter, for ease of explanation, an example is provided in which: the second node N2 is the gate node, the first node N1 is the source node, and the third node N3 is the drain node.

The scan transistor ST included in the subpixel circuit SPC illustrated in FIG. 2 can be a switching transistor for delivering a data signal VDATA, which is an image signal, to the second node N2 of the driving transistor DT.

The scan transistor ST can be turned on and off by a scan signal SC, which is a gate signal applied through a scan line SCL, which is a type of gate line GL, and can control the electrical connection between the second node N2 of the driving transistor DT and the data line DL. The drain electrode or source electrode of the scan transistor ST can be electrically connected to the data line DL. The source electrode or drain electrode of the scan transistor ST can be electrically connected to the second node N2 of the driving transistor DT. The gate electrode of the scan transistor ST can be electrically connected to the scan line SCL.

The storage capacitor Cst can be electrically connected between the first node N1 and the second node N2 of the driving transistor DT. The storage capacitor Cst can include a first capacitor electrode that is electrically connected to or corresponds to the first node N1 of the driving transistor DT, and a second capacitor electrode that is electrically connected to or corresponds to the second node N2 of the driving transistor DT.

The storage capacitor Cst is not a parasitic capacitor (e.g., Cgs, Cgd), such as an internal capacitor that can exist between the first node N1 and the second node N2 of the driving transistor DT. Instead, the storage capacitor Cst can be an external capacitor that is intentionally designed outside the driving transistor DT.

Each of the driving transistor DT and the scan transistor ST can be an n-type transistor or a p-type transistor.

The display panel 110 can have a top emission structure or a bottom emission structure.

When the display panel 110 has a top emission structure, at least a portion of the subpixel circuit SPC can overlap at least a portion of the light-emitting device ED in the vertical direction. In contrast, when the display panel 110 has a bottom emission structure, the subpixel circuit SPC may not overlap the light-emitting device ED in the vertical direction.

The subpixel circuit SPC can have a 2T1C structure that includes two transistors DT and ST and one capacitor Cst. In some cases, the subpixel circuit SPC can further include one or more additional transistors or one or more additional capacitors.

For example, the subpixel circuit SPC can have an 8T1C structure including eight transistors and one capacitor. In another example, the subpixel circuit SPC can have a 6T2C structure including six transistors and two capacitors. In yet another example, the subpixel circuit SPC can have a 7T1C structure including seven transistors and one capacitor.

Depending on the structure of the subpixel circuit SPC, the type and number of gate lines supplying gate signals to the subpixel SP can vary.

Additionally, depending on the structure of the subpixel circuit SPC, the type and number of common pixel driving voltages supplied to the subpixel SP can vary.

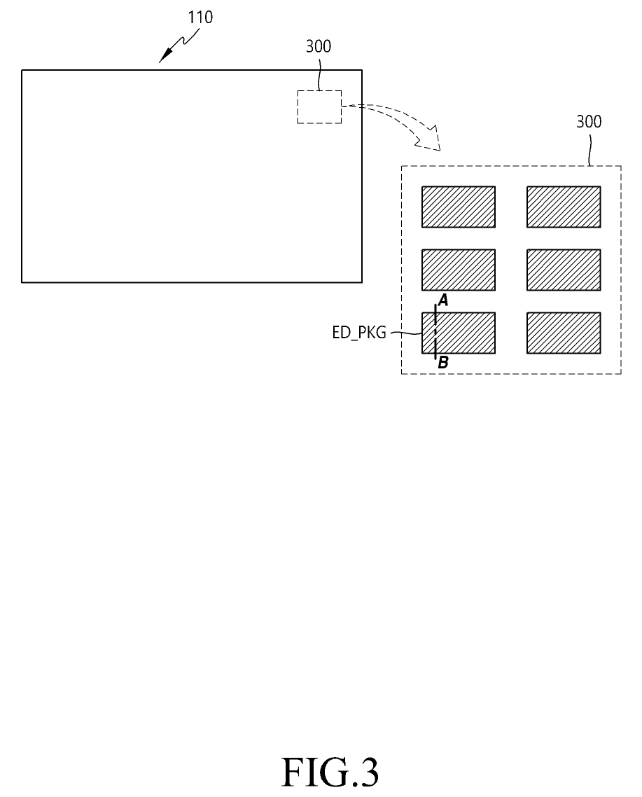

FIG. 3 is a diagram illustrating a plurality of light-emitting device packages ED_PKG arranged on the display panel 110 according to the embodiments of the present disclosure.

Referring to FIG. 3, the display panel 110 can be seen. The display panel 110 shown in FIG. 3 is the same as the display panel 110 shown in FIG. 1.

An enlarged area 300 of the display panel 110 can be seen. A plurality of light-emitting device packages ED_PKG can be arranged in the enlarged area 300.

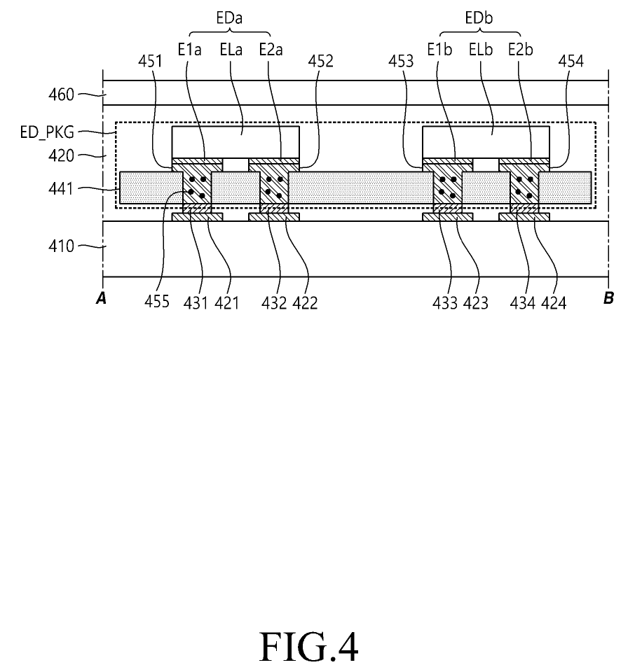

Each light-emitting device package ED_PKG can include a plurality of light-emitting devices EDa and EDb (see FIG. 4).

For example, a light-emitting device package ED_PKG can include one or more light-emitting devices EDa and EDb. The light-emitting device package ED_PKG can include red light-emitting devices EDa and EDb, blue light-emitting devices EDa and EDb, and green light-emitting devices EDa and EDb.

For example, a light-emitting device package ED_PKG can include general light-emitting devices EDa and EDb that emit light when the display device is operated and redundancy light-emitting devices EDa and EDb for repairing the display device. If a general light-emitting device EDa and EDb malfunctions, a repair process can be performed such that the redundancy light-emitting device EDa and EDb emits light.

A light-emitting device package ED_PKG can include a plurality of light-emitting devices EDa and EDb, and the plurality of light-emitting devices EDa and EDb can be arranged in a row, arranged in a circular pattern, or arranged in two columns.

In FIG. 3, an A-B region can be seen. Hereinafter, a cross-sectional view of the A-B region of the light-emitting device package ED_PKG shown in FIG. 3 will be described in detail.

FIG. 4 is a cross-sectional view of the A-B region of the light-emitting device package ED_PKG shown in FIG. 3.

Referring to FIG. 4, a lower substrate 410 can be disposed at the bottom of the display panel 110. The lower substrate 410 can include the substrate 111 shown in FIG. 1. The lower substrate 410 can also include the transistors DT and ST and the storage capacitor Cst shown in FIG. 2.

A first connection electrode 421 and a second connection electrode 422 can be disposed on the lower substrate 410. The first connection electrode 421 and the second connection electrode 422 can include a metallic material. The first connection electrode 421 and the second connection electrode 422 can supply voltage or current to the light-emitting devices EDa.

The first connection electrode 421 and the second connection electrode 422 can be positioned adjacent to each other but spaced apart. When a first voltage is supplied to the first connection electrode 421, a second voltage can be supplied to the second connection electrode 422. The first voltage can have a different voltage level from the second voltage. The first voltage can be greater than or less than the second voltage.

A first bonding material 431 can be disposed on the first connection electrode 421. The first bonding material 431 can include a conductive material. Since the first bonding material 431 is disposed in contact with the first connection electrode 421, the first bonding material 431 can be electrically connected to the first connection electrode 421. Referring to FIG. 4, the width of the first bonding material 431 can be smaller than the width of the first connection electrode 421. The first bonding material 431 can be positioned between the first connection electrode 421 and the light-emitting device package ED_PKG. The first bonding material 431 can secure the light-emitting device package ED_PKG to the first connection electrode 421.

A second bonding material 432 can be disposed on the second connection electrode 422. The second bonding material 432 can include a conductive material. Since the second bonding material 432 is disposed in contact with the second connection electrode 422, the second bonding material 432 can be electrically connected to the second connection electrode 422. Referring to FIG. 4, the width of the second bonding material 432 can be smaller than the width of the second connection electrode 422. The second bonding material 432 can be positioned between the second connection electrode 422 and the light-emitting device package ED_PKG. The second bonding material 432 can secure the light-emitting device package ED_PKG to the second connection electrode 422.

The third connection electrode 423 can be positioned apart from the first connection electrode 421 and the second connection electrode 422. The characteristics of the third connection electrode 423 can be the same as those of the first connection electrode 421. The fourth connection electrode 424 can be disposed adjacent to the third connection electrode 423 but positioned apart from the third connection electrode 423. The characteristics of the fourth connection electrode 424 can be the same as those of the second connection electrode 422. The third connection electrode 423 and the fourth connection electrode 424 can supply voltage or current to the light-emitting devices EDb. A third bonding material 433 can be disposed on the third connection electrode 423, and the characteristics of the third bonding material 433 can be the same as those of the first bonding material 431. A fourth bonding material 434 can be disposed on the fourth connection electrode 424, and the characteristics of the fourth bonding material 434 can be the same as those of the second bonding material 432.

The light-emitting device package ED_PKG can be disposed on the lower substrate 410.

The light-emitting device package ED_PKG can include a package substrate 441, a plurality of anchors 451, 452, 453, and 454, and a plurality of light-emitting devices EDa and EDb.

The package substrate 441 can be disposed at the bottom of the light-emitting device package ED_PKG. Etching, deposition, and patterning processes can be performed on the package substrate 441. The package substrate 441 can include a material capable of undergoing etching, deposition, and patterning processes. The package substrate 441 can be a glass substrate. The package substrate 441 can include a polymer-based material or a silicon-based material.

The plurality of anchors 451, 452, 453, and 454 can penetrate through the package substrate 441. The package substrate 441 can include a plurality of anchor holes AH, and the plurality of anchors 451, 452, 453, and 454 can be disposed in the plurality of anchor holes AH of the package substrate 441, respectively. The plurality of anchors 451, 452, 453, and 454 can have a cylindrical shape. The plurality of anchors 451, 452, 453, and 454 can have a cylindrical shape, but the top surfaces of the anchors can have a larger diameter than the lower portions. However, the entire portion of the plurality of anchors 451, 452, 453, and 454 can also have a cylindrical shape.

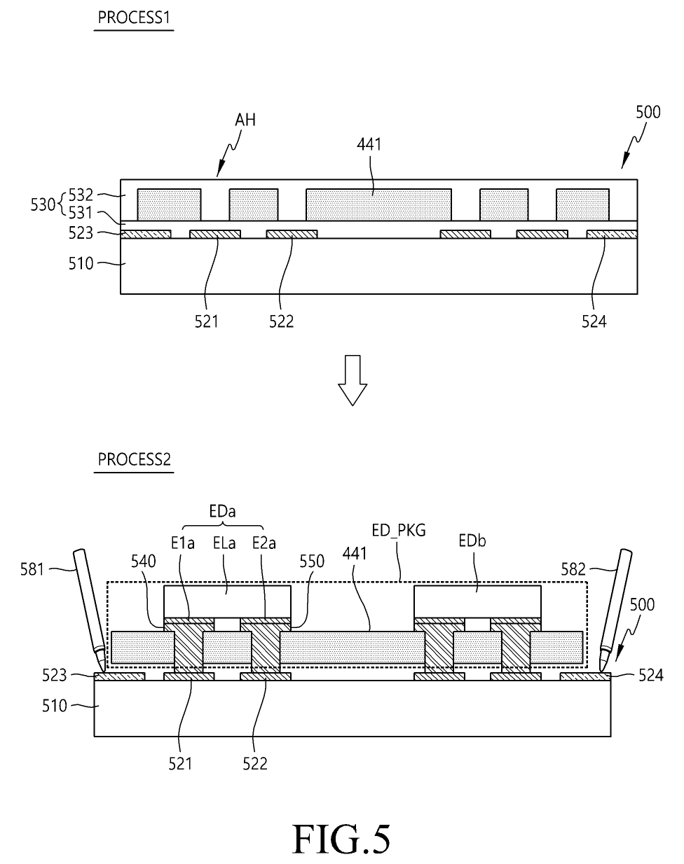

The plurality of anchors 451, 452, 453, and 454 can include nano-conductive balls 455. The plurality of anchors 451, 452, 453, and 454 can be formed of a conductive paste 530 (see FIG. 5) material containing nano-conductive balls 455. When subjected to thermo-compression, the conductive paste 530 can be cured, and the nano-conductive balls 455 can be broken. Accordingly, the plurality of anchors 451, 452, 453, and 454 can become rigid and can have conductivity. When thermo-compression is applied to the plurality of anchors 451, 452, 453, and 454, all of the nano-conductive balls 455 can be broken. However, some of the nano-conductive balls 455 can remain unbroken inside the plurality of anchors 451, 452, 453, and 454.

Referring to FIG. 4, the first anchor 451 can be positioned adjacent to but spaced apart from the second anchor 452. The third anchor 453 can be positioned adjacent to but spaced apart from the fourth anchor 454.

The first anchor 451 can overlap the first bonding material 431. In this case, the first anchor 451 can be disposed in contact with the first bonding material 431. The diameter of the first anchor 451 can be the same as the diameter of the first bonding material 431, but it is not limited thereto. The second anchor 452 can overlap the second bonding material 432. In this case, the second anchor 452 can be disposed in contact with the second bonding material 432. The diameter of the second anchor 452 can be the same as the diameter of the second bonding material 432, but it is not limited thereto. The third anchor 453 can overlap the third bonding material 433. In this case, the third anchor 453 can be disposed in contact with the third bonding material 433. The diameter of the third anchor 453 can be the same as the diameter of the third bonding material 433, but it is not limited thereto. The fourth anchor 454 can overlap the fourth bonding material 434. In this case, the fourth anchor 454 can be disposed in contact with the fourth bonding material 434. The diameter of the fourth anchor 454 can be the same as the diameter of the fourth bonding material 434, but it is not limited thereto.

The light-emitting device package ED_PKG can include a first light-emitting device EDa and a second light-emitting device EDb. The light-emitting device package ED_PKG can include two or more light-emitting devices EDa and EDb. However, in the cross-sectional view of the A-B region shown in FIG. 4, two light-emitting devices EDa and EDb are illustrated.

The first light-emitting device EDa can include: a first emission layer ELa, a first positive electrode E1a positioned below the first emission layer ELa, and a first negative electrode E2a positioned below the first emission layer ELa.

The first light-emitting device EDa can be disposed on the first anchor 451 and the second anchor 452.

The first positive electrode E1a of the first light-emitting device EDa can be disposed in contact with the first anchor 451. The first positive electrode E1a can overlap the first anchor 451. Since the first anchor 451 can include a conductive material, the first positive electrode E1a can be electrically connected to the first anchor 451.

The first negative electrode E2a of the first light-emitting device EDa can be disposed in contact with the second anchor 452. The first negative electrode E2a can overlap the second anchor 452. Since the second anchor 452 can include a conductive material, the first negative electrode E2a can be electrically connected to the second anchor 452.

As the first positive electrode E1a is electrically connected to the first anchor 451 and the first negative electrode E2a is electrically connected to the second anchor 452, the first light-emitting device EDa can be driven to emit light.

The second light-emitting device EDb can include a second emission layer ELb, a second positive electrode E1b positioned below the second emission layer ELb, and a second negative electrode E2b positioned below the second emission layer ELb.

The second light-emitting device EDb can be disposed on the third anchor 453 and the fourth anchor 454.

The second positive electrode E1b of the second light-emitting device EDb can be disposed in contact with the third anchor 453. The second positive electrode E1b can overlap the third anchor 453. Since the third anchor 453 can include a conductive material, the second positive electrode E1b can be electrically connected to the third anchor 453.

The second negative electrode E2b of the second light-emitting device EDb can be disposed in contact with the fourth anchor 454. The second negative electrode E2b can overlap the fourth anchor 454. Since the fourth anchor 454 can include a conductive material, the second negative electrode E2b can be electrically connected to the fourth anchor 454.

As the second positive electrode E1b is electrically connected to the third anchor 453 and the second negative electrode E2b is electrically connected to the fourth anchor 454, the second light-emitting device EDb can be driven to emit light.

An insulating layer 420 can be disposed on the lower substrate 410. The insulating layer 420 can be disposed to cover the light-emitting device package ED_PKG. The insulating layer 420 can include an organic material. The insulating layer 420 can secure the position of the light-emitting device package ED_PKG.

A protective layer 460 can be disposed on the insulating layer 420. The protective layer 460 can protect the light-emitting device package ED_PKG from external factors. The protective layer 460 can be a glass substrate, and it can also include an organic material or an inorganic material.

Although the light-emitting device EDa and EDb are described as flip-chip type LEDs for illustration purposes, the present disclosure can also be applied to vertical-type LEDs. In this case, the first electrode of the vertical-type LED can overlap a single anchor. The second electrode, different from the first electrode, can receive power through an anchor, but it can also receive power from a component external to the light-emitting device package. For ease of explanation, the present disclosure will be described assuming that the light-emitting device is a flip-chip type LED.

The cross-sectional view of the A-B region has been described. Hereinafter, the light-emitting device package ED_PKG will be described in more detail.

FIGS. 5 to 8 are diagrams illustrating a process of transferring the light-emitting device package ED_PKG onto the lower substrate 410 according to the embodiments of the present disclosure.

Referring to FIG. 5, a first process (PROCESS1) and a second process (PROCESS2) can be seen. Since the second process (PROCESS2) is performed after the first process (PROCESS1), the first process (PROCESS1) will be described first.

An inspection wafer 500 can include an inspection substrate 510, inspection electrodes, probe electrodes, a package substrate 441, and a conductive paste 530.

The inspection substrate 510 can be disposed at the bottom of the light-emitting device package ED_PKG. Etching, deposition, and patterning processes can be performed on the inspection substrate 510. The inspection substrate 510 can include a material capable of undergoing etching, deposition, and patterning processes. The inspection substrate 510 can be a glass substrate. The inspection substrate 510 can include a polymer-based material or a silicon-based material.

A first inspection electrode 521 and a second inspection electrode 522 can be disposed on the inspection substrate 510. The first inspection electrode 521 and the second inspection electrode 522 can overlap a single light-emitting device EDa or EDb. As the first inspection electrode 521 and the second inspection electrode 522 supply power to the light-emitting device EDa or EDb, the light-emitting device EDa or EDb can emit light. The first inspection electrode 521 and the second inspection electrode 522 can include a metallic material.

A first probe electrode 523 and a second probe electrode 524 can be disposed on the inspection substrate 510. The first probe electrode 523 and the second probe electrode 524 can be electrodes to which inspection equipment is connected. The first probe electrode 523 can be electrically connected to the first inspection electrode 521. The second probe electrode 524 can be electrically connected to the second inspection electrode 522. The wiring connecting the first probe electrode 523 to the first inspection electrode 521 can be disposed on the upper surface of the inspection substrate 510 or within the inspection substrate 510. The wiring connecting the second probe electrode 524 to the second inspection electrode 522 can be disposed on the upper surface of the inspection substrate 510 or within the inspection substrate 510.

A first conductive paste 531 can be disposed on the inspection substrate 510. The first conductive paste 531 can be disposed to cover the inspection electrodes and probe electrodes. The first conductive paste 531 can include nano-conductive balls 455. When subjected to thermo-compression, the first conductive paste 531 can be cured.

The package substrate 441 can be disposed on the first conductive paste 531. The package substrate 441 can include a plurality of anchor holes AH. Referring to FIG. 5, four anchor holes included in the package substrate 441 can be seen.

A second conductive paste 532 can be disposed on the package substrate 441. The characteristics of the second conductive paste 532 can be the same as those of the first conductive paste 531. The second conductive paste 532 can fill the plurality of anchor holes AH included in the package substrate 441. Since the first conductive paste 531 and the second conductive paste 532 are made of the same material, the second conductive paste 532 can integrate with the first conductive paste 531. The conductive paste 530 can include the first conductive paste 531 and the second conductive paste 532.

After the second conductive paste 532 is disposed, an exposure process can be performed. As the exposure process is performed, a portion of the second conductive paste 532 can be removed. Referring to FIG. 5, the steps before the exposure process correspond to the first process (PROCESS1). After the first process (PROCESS1) is performed, the second process (PROCESS2) can be performed.

The second process (PROCESS2) can be seen. Referring to FIG. 5, after the plurality of light-emitting devices EDa and EDb are disposed on the conductive paste 530, a thermo-compression process can be performed. The thermo-compression process can be a process that applies force to the light-emitting devices EDa and EDb from the upper surface toward the lower surface. When the thermo-compression process is performed, heat can be transferred to the light-emitting devices EDa and EDb and the inspection wafer 500. Accordingly, a portion of the conductive paste 530 can be cured, thereby forming a plurality of anchor posts 540 and 550.

The plurality of anchor posts 540 and 550 can be positioned within the plurality of anchor holes AH, respectively. The plurality of anchor posts 540 and 550 can include the nano-conductive balls 455 shown in FIG. 4. The plurality of anchor posts 540 and 550 can overlap the electrodes of the light-emitting devices EDa and EDb. The plurality of anchor posts 540 and 550 can overlap the inspection electrodes. After the plurality of anchor posts 540 and 550 are formed through the thermo-compression process, the conductive paste 530, excluding the plurality of anchor posts 540 and 550, can be removed.

The plurality of light-emitting devices EDa and EDb can be disposed on the plurality of anchor posts 540 and 550. In this case, a light emission inspection process can be performed on the plurality of light-emitting devices EDa and EDb.

The light emission inspection process can be a process for determining whether the plurality of light-emitting devices EDa and EDb emit light normally. During the light emission inspection process, a first inspection probe 581 can be brought into contact with the first probe electrode 523, and a second inspection probe 582 can be brought into contact with the second probe electrode 524. The first inspection probe 581 and the second inspection probe 582 can supply power to the inspection wafer 500 to drive the light-emitting devices EDa and EDb.

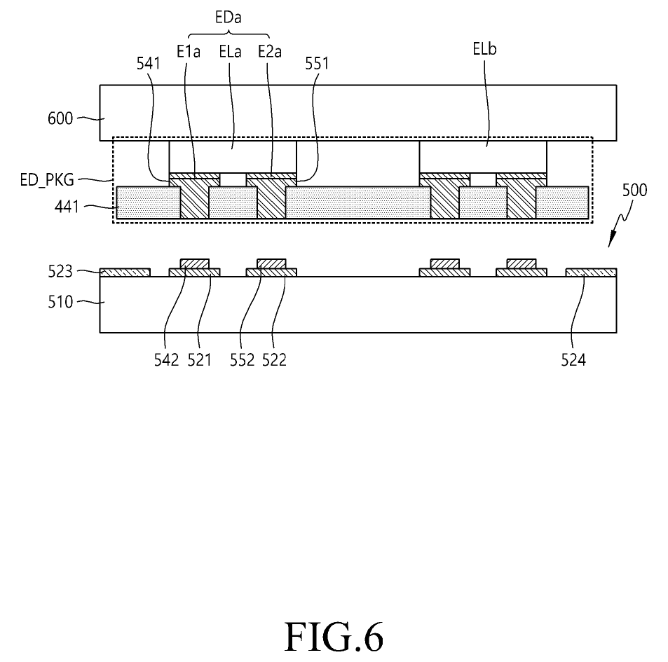

If the light-emitting devices EDa and EDb are determined to be normal in the light emission inspection process, the package substrate 441 can be moved away from the inspection substrate 510. Referring to FIG. 6, a stamp 600 can be attached to the upper surface of the light-emitting devices EDa and EDb, and the stamp 600 can lift the light-emitting devices EDa and EDb upward.

Referring to FIG. 6, as the package substrate 441 moves away from the inspection substrate 510, the plurality of anchor posts 540 and 550 can be separated into a plurality of anchors 541 and 551 and a plurality of wafer anchors 542 and 552. For example, a portion of the plurality of anchor posts 540 and 550 can remain as the plurality of anchors 541 and 551 within the light-emitting device package ED_PKG, while the remaining portion of the plurality of anchor posts 540 and 550 can remain as the plurality of wafer anchors 542 and 552 within the inspection wafer 500.

When the plurality of anchor posts 540 and 550 are separated into the plurality of anchors 541 and 551 and the plurality of wafer anchors 542 and 552, the cross-sections of the plurality of anchors 541 and 551 and the plurality of wafer anchors 542 and 552 can be separated flatly. In this case, the bottom surfaces of the plurality of anchors 541 and 551 can be positioned parallel to the bottom surface of the package substrate 441. For example, the distance from the light-emitting devices EDa and EDb to the bottom surfaces of the plurality of anchors 541 and 551 can be the same as the distance from the light-emitting devices EDa and EDb to the bottom surface of the package substrate 441.

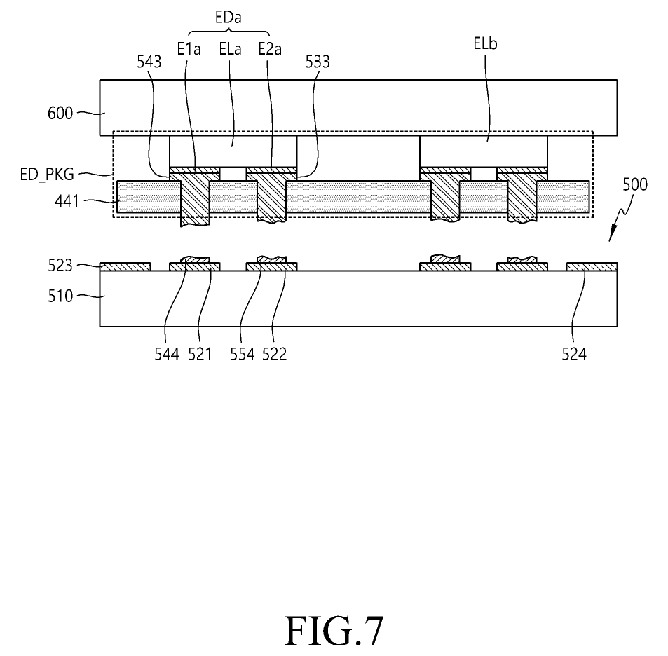

Referring to FIG. 7, when the plurality of anchor posts 540 and 550 are separated into the plurality of anchors 541 and 551 and the plurality of wafer anchors 542 and 552, the cross-sections of the plurality of anchors 541 and 551 and the plurality of wafer anchors 542 and 552 can be separated unevenly. A bottom surface of the anchor 541 can have a different shape from a bottom surface of the anchor 551. The distance from the light-emitting devices EDa and EDb to the bottom surfaces of the plurality of anchors 541 and 551 can be greater than the distance from the light-emitting devices EDa and EDb to the bottom surface of the package substrate 441.

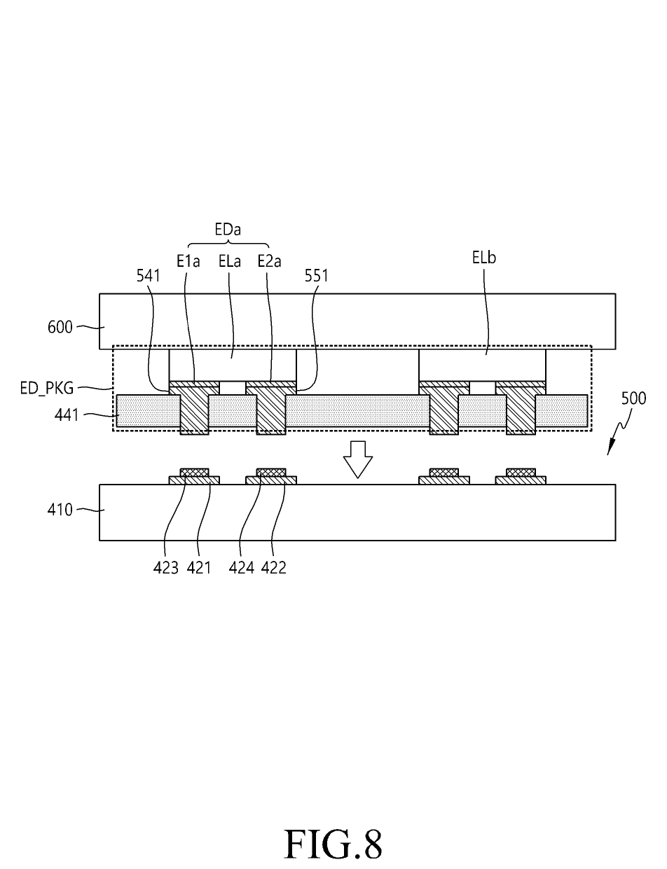

Referring to FIG. 8, the light-emitting device package ED_PKG can be positioned on the lower substrate 410. Then, as the stamp 600 moves in a direction approaching the lower substrate 410, the light-emitting device package ED_PKG can come into contact with the bonding materials 431 and 432.

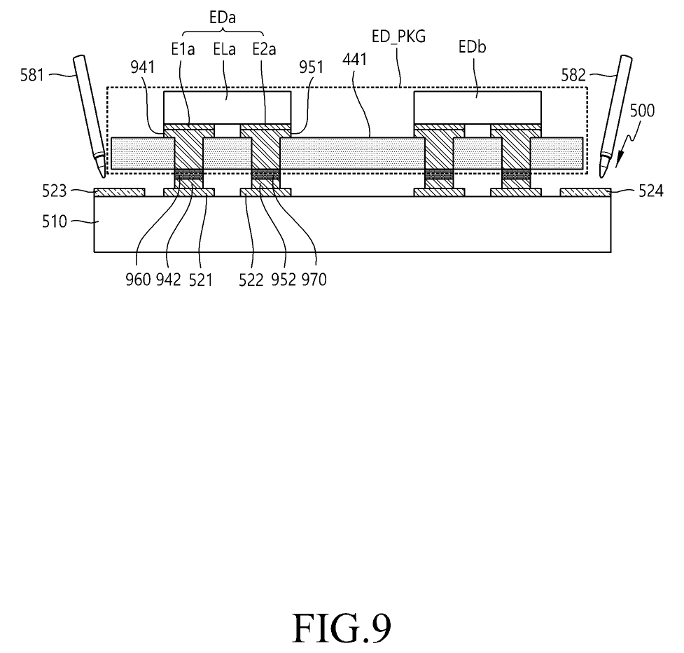

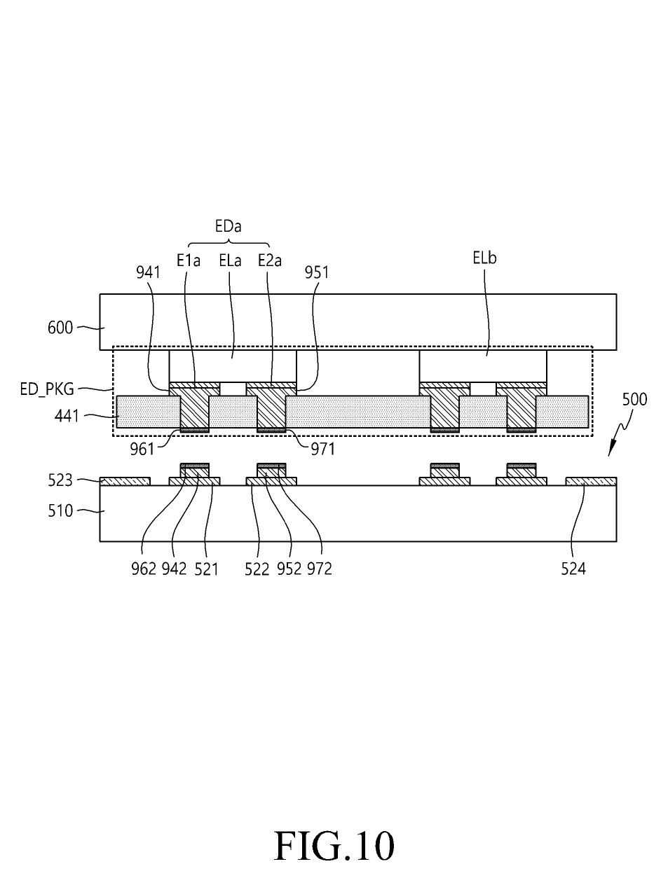

FIGS. 9 and 10 are diagrams illustrating a process of transferring the light-emitting device package ED_PKG onto the lower substrate 410 according to the embodiments of the present disclosure.

Referring to FIG. 9, the inspection wafer 500 and the light-emitting device package ED_PKG can be seen. The features of the inspection wafer 500 and the light-emitting device package ED_PKG shown in FIGS. 9 and 10 can be the same as those of the inspection wafer 500 and the light-emitting device package ED_PKG shown in FIGS. 5 to 8, and therefore, a redundant description can be omitted or may be briefly provided.

Referring to FIG. 9, a plurality of conductive thin film prototypes 960 and 970 can be positioned between the plurality of anchors 941 and 951 and the plurality of wafer anchors 942 and 952. A first conductive thin film prototype 960 can be positioned between the first anchor 941 and the first wafer anchor 942. A second conductive thin film prototype 970 can be positioned between the second anchor 951 and the second wafer anchor 952. The plurality of conductive thin film prototypes 960 and 970 can have a thin film form and can include a conductive material.

The plurality of conductive thin film prototype 960 and 970 can include nano-materials with conductivity, such as carbon black, graphene, or silver nanowires.

The plurality of conductive thin film prototypes 960 and 970 can include a material with weak adhesion. Accordingly, the plurality of thin films can be easily separated from the plurality of anchors 941 and 951 and the plurality of wafer anchors 942 and 952.

Referring to FIG. 10, the light-emitting device package ED_PKG can be separated from the inspection wafer 500. In this case, the conductive thin film prototypes 960 and 970 can be separated into a plurality of conductive thin films 961 and 971 and a plurality of wafer conductive thin films 962 and 972. The light-emitting device package ED_PKG can include the plurality of conductive thin films 961 and 971. The plurality of conductive thin films 961 and 971 can be positioned below the plurality of anchors 941 and 951.

However, the plurality of conductive thin film prototypes 960 and 970 may not be separated into two parts but instead can be entirely included in the light-emitting device package ED_PKG. In this case, the plurality of conductive thin film prototypes 960 and 970 can be positioned below the plurality of anchors 941 and 951. Since the plurality of conductive thin film prototypes 960 and 970 include a material with weak adhesion, they can be easily separated from the plurality of anchors 941 and 951 and the plurality of wafer anchors 942 and 952.

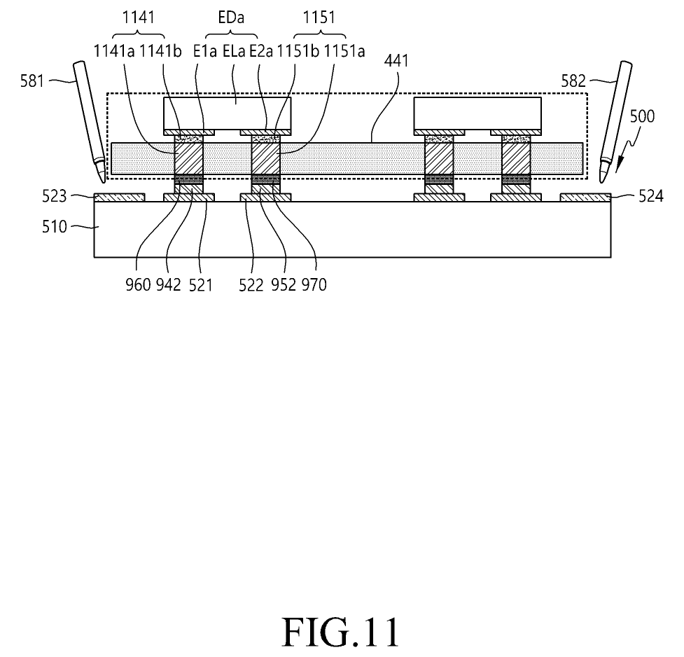

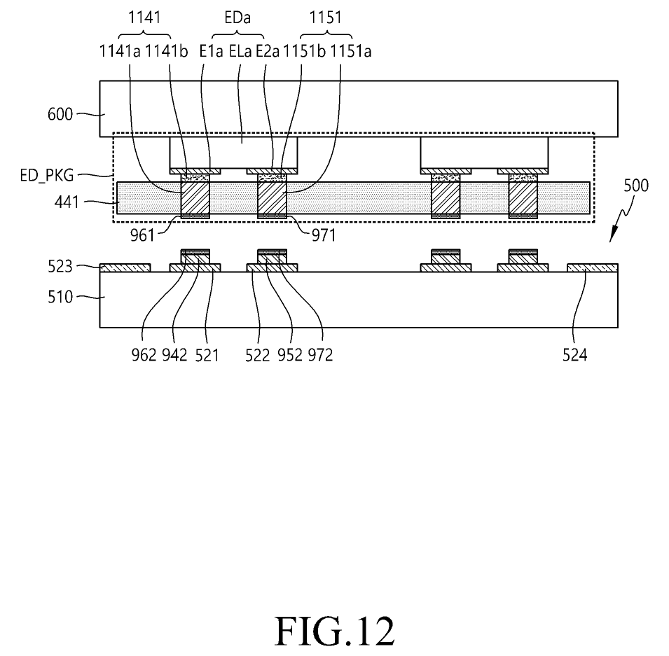

FIGS. 11 and 12 are diagrams illustrating a process of transferring the light-emitting device package ED_PKG onto the lower substrate 410 according to the embodiments of the present disclosure.

Referring to FIGS. 11 and 12, the inspection wafer 500 and the light-emitting device package ED_PKG can be seen. The features of the inspection wafer 500 and the light-emitting device package ED_PKG shown in FIG. 11 and FIG. 12 can be the same as those of the inspection wafer 500 and the light-emitting device package ED_PKG shown in FIG. 9 and FIG. 10. Accordingly, a redundant description can be omitted.

As the light-emitting device package ED_PKG is moved by the stamp 600, the plurality of conductive thin film prototypes 960 and 970 can be separated into two parts.

Referring to FIG. 12, the light-emitting device package ED_PKG can include the package substrate 441, a plurality of anchors 1141 and 1151, and a plurality of light-emitting devices EDa and EDb.

The plurality of anchors 1141 and 1151 can be positioned in the plurality of anchor holes AH (see FIGS. 4 and 5) formed in the package substrate 441.

The plurality of anchors 1141 and 1151 can include anchor electrode posts 1141a and 1151a and anchor electrodes 1141b and 1151b.

The anchor electrode posts 1141a and 1151a can be positioned in the plurality of anchor holes AH. The plurality of anchor electrode posts 1141a and 1151a can include a metal material.

The anchor electrodes 1141b and 1151b can be disposed on the plurality of anchor electrode posts 1141a and 1151a. The anchor electrodes 1141b and 1151b can include a metal material. The anchor electrodes 1141b and 1151b can include a metal different from that of the plurality of anchor electrode posts 1141a and 1151a or can include the same metal. The anchor electrodes 1141b and 1151b can be electrically connected to the plurality of anchor electrode posts 1141a and 1151a through a eutectic bonding process.

Referring to FIG. 12, the plurality of conductive thin films 961 and 971 can be positioned below the plurality of anchor electrode posts 1141a and 1151a, respectively. Since the anchor electrodes 1141b and 1151b, the plurality of anchor electrode posts 1141a and 1151a, and the plurality of conductive thin films 961 and 971 are conductive, they can be electrically connected to each other.

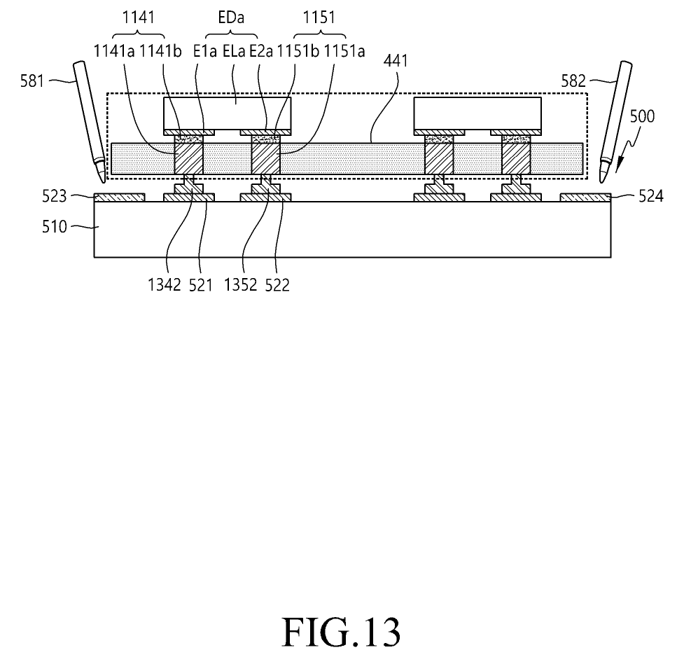

FIGS. 13 to 16 are diagrams illustrating a process of transferring the light-emitting device package ED_PKG onto the lower substrate 410 according to the embodiments of the present disclosure.

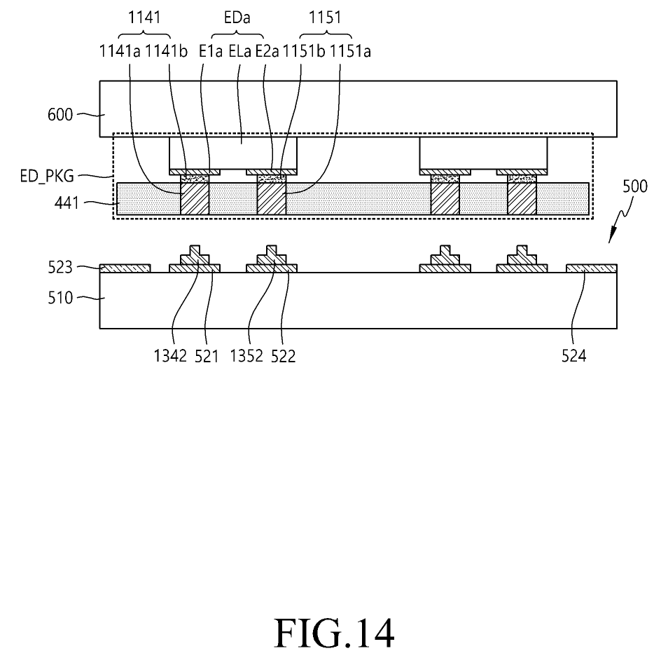

Referring to FIGS. 13 and 14, the inspection wafer 500 and the light-emitting device package ED_PKG can be seen. Some features of FIGS. 13 and 14 are the same as those of FIGS. 11 and 12, so a redundant description can be omitted or may be briefly provided.

The stamp 600 can be attached to the upper surfaces of the light-emitting devices EDa and EDb. By the stamp 600, the package substrate 441 can move away from the inspection substrate 510. Accordingly, the light-emitting device package ED_PKG can be separated from the inspection wafer 500 while remaining attached to the stamp 600.

The plurality of wafer anchors 1342 and 1352 can have an uneven structure. The bottom surfaces of the plurality of wafer anchors 1342 and 1352 can be wider than their top surfaces. The plurality of wafer anchors 1342 and 1352 can have a bottom surface with a greater width than the top surface. The plurality of wafer anchors 1342 and 1352 can have a structure in which a larger-diameter cylinder is positioned at the bottom, with a smaller-diameter cylinder positioned on top.

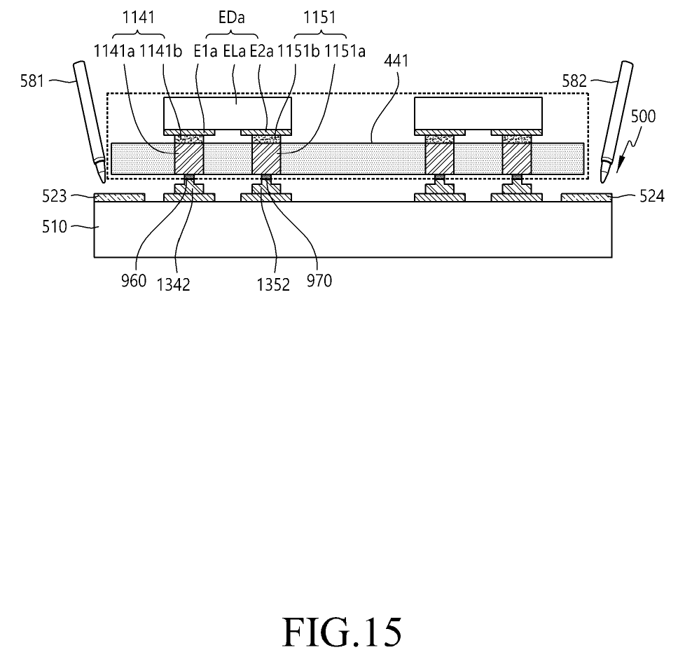

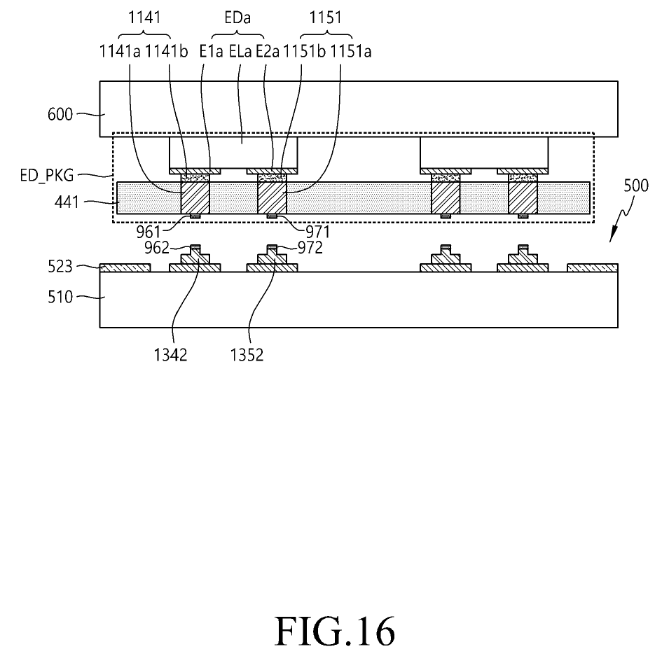

Referring to FIGS. 15 and 16, the plurality of conductive thin film prototypes 960 and 970 can be disposed on the plurality of wafer anchors 1342 and 1352, respectively. When the light-emitting device package ED_PKG is separated from the inspection wafer 500, the conductive thin film prototypes 960 and 970 can be divided into two parts.

Referring to FIG. 16, the plurality of conductive thin films 961 and 971 can be positioned below the plurality of anchor electrode posts 1141a and 1151a. The plurality of wafer conductive thin films 962 and 972 can be positioned on the plurality of wafer anchors 1342 and 1352. However, the plurality of conductive thin film prototypes 960 and 970 may not be divided into two parts and instead can be entirely included in the light-emitting device package ED_PKG. In this case, the plurality of conductive thin film prototypes 960 and 970 can be positioned below the plurality of anchors 1141 and 1151. Since the plurality of conductive thin film prototypes 960 and 970 include a material with weak adhesion, they can be easily separated from the plurality of anchors 1141 and 1151 and the plurality of wafer anchors 1342 and 1352. A diameter or width of the plurality of conductive thin films 961 and 971 can be smaller than a diameter or width of the plurality of anchor electrode posts 1141a and 1151a, respectively.

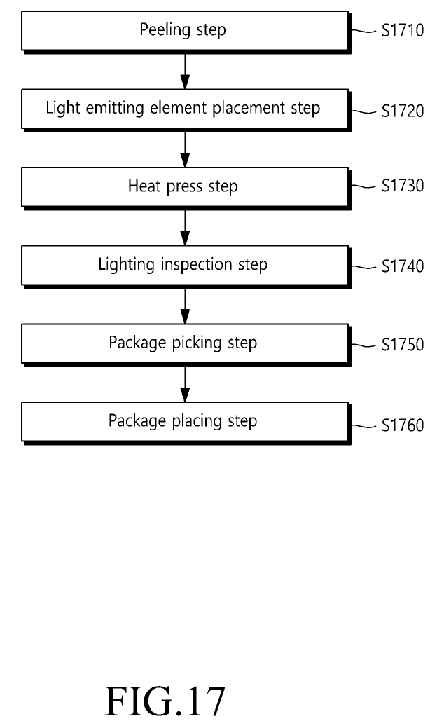

Hereinafter, a method of manufacturing a light-emitting device package according to an embodiment of the present disclosure will be described in detail. FIG. 17 is a flowchart of a method of manufacturing a light-emitting device package according to the embodiments of the present disclosure.

Referring to FIG. 17, according to one embodiment, a filling step (S1710) can be performed in which a conductive paste is filled into a plurality of anchor holes of a package substrate. The conductive paste can be a material that can be transformed into a fixed structure by the application of heat and pressure in a subsequent process.

Next, a light-emitting device placement step (S1720) can be performed in which a plurality of light-emitting devices are placed on the conductive paste. The plurality of light-emitting devices can be aligned on corresponding portions of the conductive paste, thereby forming a basis for electrical connection and mechanical fixation in later processes.

Subsequently, a thermo-compression step (S1730) can be carried out in which heat and external force are applied to the plurality of light-emitting devices. In this step, the conductive paste can be cured or deformed to form a plurality of anchor posts, which can securely fix the respective light-emitting devices in position.

Following this, a lighting inspection step (S1740) can be performed. In the lighting inspection step, power can be supplied to the plurality of anchor posts through probe electrodes on a wafer substrate, and it can be inspected whether the plurality of light-emitting devices emit light. Through this step, it can be possible to distinguish acceptable products from defective ones.

According to an embodiment, in addition to the above steps, a package picking step (S1750) can further be included. In the package picking step, a stamp can move the plurality of light-emitting devices away from the wafer substrate, and accordingly, the plurality of anchor posts can be separated into a plurality of anchors and a plurality of wafer anchors.

Furthermore, a package placing step (S1760) can also be included. In the package placing step, a light-emitting device package including the package substrate, the plurality of light-emitting devices disposed on the package substrate, and the plurality of anchors overlapping the light-emitting devices, can be placed in contact with a bonding material on a lower substrate.

Accordingly, with this configuration, it can be possible to manufacture a light-emitting device package that ensures high reliability in the fixation of the light-emitting devices, while also enabling process optimization and suitability for mass production.

A display device according to the embodiments of the present disclosure can be described as follows.

The embodiments of the present disclosure can provide a display device comprising a lower substrate; a plurality of connection electrodes disposed on the lower substrate; a package substrate disposed on the plurality of connection electrodes; a first light-emitting device comprising a first emission layer, and a first electrode and a second electrode positioned below the first emission layer, the first light-emitting device being disposed on the package substrate; a second light-emitting device comprising a second emission layer, and a third electrode and a fourth electrode positioned below the second emission layer, the second light-emitting device being disposed on the package substrate; a first anchor electrically connected to the first electrode and a first connection electrode of the plurality of connection electrodes, penetrating through the package substrate, and overlapping the first electrode and the first connection electrode; a second anchor electrically connected to the second electrode and a second connection electrode of the plurality of connection electrodes, penetrating through the package substrate, and overlapping the second electrode and the second connection electrode; a third anchor electrically connected to the third electrode and a third connection electrode of the plurality of connection electrodes, penetrating through the package substrate, and overlapping the third electrode and the third connection electrode; and a fourth anchor electrically connected to the fourth electrode and a fourth connection electrode of the plurality of connection electrodes, penetrating through the package substrate, and overlapping the fourth electrode and the fourth connection electrode.

A first bottom surface of the first anchor can be positioned farther from the first light-emitting device than a bottom surface of the package substrate.

The first bottom surface of the first anchor can have a different shape from a second bottom surface of the second anchor.

The first to fourth anchors can include a material that is cured and becomes conductive when subjected to heat and external force.

The display device can further comprise a first bonding material disposed between the first connection electrode and the first anchor, having conductivity, and securing the first anchor to the first connection electrode; a second bonding material disposed between the second connection electrode and the second anchor, having conductivity, and securing the second anchor to the second connection electrode; a third bonding material disposed between the third connection electrode and the third anchor, having conductivity, and securing the third anchor to the third connection electrode; and a fourth bonding material disposed between the fourth connection electrode and the fourth anchor, having conductivity, and securing the fourth anchor to the fourth connection electrode.

The display device can further comprise a first conductive thin film disposed below the first anchor and having conductivity; a second conductive thin film disposed below the second anchor and having conductivity; a third conductive thin film disposed below the third anchor and having conductivity; and a fourth conductive thin film disposed below the fourth anchor and having conductivity.

The first to fourth conductive thin films can include at least one material selected from carbon black, graphene, and silver nanowires.

At least one of the first to fourth anchors can further include nano-conductive balls, which are conductive and broken upon receiving external force.

The first anchor can comprise a first anchor electrode post including a first metal material, and a first anchor electrode disposed on the first anchor electrode post and including a second metal material. The second anchor can comprise a second anchor electrode post including the first metal material, and a second anchor electrode disposed on the second anchor electrode post and including the second metal material. The third anchor can comprise a third anchor electrode post including the first metal material, and a third anchor electrode disposed on the third anchor electrode post and including the second metal material. The fourth anchor can comprise a fourth anchor electrode post including the first metal material, and a fourth anchor electrode disposed on the fourth anchor electrode post and including the second metal material.

The first metal material can be different from the second metal material.

The display device can further comprise a first conductive thin film disposed below the first anchor electrode post and having conductivity; a second conductive thin film disposed below the second anchor electrode post and having conductivity; a third conductive thin film disposed below the third anchor electrode post and having conductivity; and a fourth conductive thin film disposed below the fourth anchor electrode post and having conductivity.

A diameter or width of the first to fourth conductive thin films can be smaller than a diameter or width of the first to fourth anchor electrode posts, respectively.

The package substrate can include at least one material selected from glass, a polymer-based material, and a silicon-based material.

The first to fourth anchors can comprise a conductive material, wherein the conductive material can include at least one material selected from a metal material, a polymer-based material, and a ceramic material.

The embodiments of the present disclosure can provide a light-emitting device package comprising a package substrate; a first light-emitting device disposed on the package substrate, comprising a first emission layer, a first electrode electrically connected to the first emission layer, and a second electrode electrically connected to the first emission layer; a second light-emitting device disposed on the package substrate, comprising a second emission layer, a third electrode electrically connected to the second emission layer, and a fourth electrode electrically connected to the second emission layer; a first anchor that is electrically connected to the first electrode, overlaps the first electrode, and penetrates through the package substrate; and a second anchor that is electrically connected to the third electrode, overlaps the third electrode, and penetrates through the package substrate.

A first bottom surface of the first anchor can be positioned farther from the first light-emitting device than a bottom surface of the package substrate.

The first bottom surface of the first anchor can have a different shape from a second bottom surface of the second anchor.

The light-emitting device can further comprises: a third anchor electrically connected to the second electrode, overlapping with the second electrode, and penetrating through the package substrate; and a fourth anchor electrically connected to the fourth electrode, overlapping with the fourth electrode, and penetrating through the package substrate.

The embodiments of the present disclosure can provide a method of manufacturing a light-emitting device package, comprising a filling step of filling a conductive paste into a plurality of anchor holes of a package substrate; a light-emitting device placement step of placing a plurality of light-emitting devices on the conductive paste; a thermo-compression step of applying heat and external force to the plurality of light-emitting devices, thereby converting the conductive paste into a plurality of anchor posts; and a light emission inspection step of supplying power to the plurality of anchor posts through probe electrodes on a wafer substrate and inspecting whether the plurality of light-emitting devices emit light.

The method can further comprise a package picking step, wherein a stamp moves the plurality of light-emitting devices away from the wafer substrate, and the plurality of anchor posts are separated into a plurality of anchors and a plurality of wafer anchors.

The method can further comprise a package placing step, wherein the light-emitting device package, including the package substrate, the plurality of light-emitting devices on the package substrate, and the plurality of anchors overlapping the plurality of light-emitting devices, comes into contact with a bonding material on a lower substrate.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein can be applied to other embodiments and applications without departing from the spirit and scope of the present invention. The above description and the accompanying drawings provide an example of the technical idea of the present invention for illustrative purposes only. For example, the disclosed embodiments are intended to illustrate the scope of the technical idea of the present invention.

What is claimed is:

1. A display device comprising:
a lower substrate;
a plurality of connection electrodes disposed on the lower substrate;
a package substrate disposed on the plurality of connection electrodes;
a first light-emitting device disposed on the package substrate, and comprising a first light-emitting layer, and a first electrode and a second electrode that are positioned below the first light-emitting layer;
a second light-emitting device disposed on the package substrate, and comprising a second light-emitting layer, and a third electrode and a fourth electrode that are positioned below the second light-emitting layer;
a first anchor electrically connected to the first electrode and a first connection electrode of the plurality of connection electrodes, the first anchor penetrating through the package substrate and overlapping with the first electrode and the first connection electrode;
a second anchor electrically connected to the second electrode and a second connection electrode of the plurality of connection electrodes, the second anchor penetrating through the package substrate and overlapping with the second electrode and the second connection electrode;
a third anchor electrically connected to the third electrode and a third connection electrode of the plurality of connection electrodes, the third anchor penetrating through the package substrate and overlapping with the third electrode and the third connection electrode; and
a fourth anchor electrically connected to the fourth electrode and a fourth connection electrode of the plurality of connection electrodes, the fourth anchor penetrating through the package substrate and overlapping with the fourth electrode and the fourth connection electrode.

2. The display device according to claim 1, wherein a first bottom surface of the first anchor is positioned farther from the first light-emitting device than a bottom surface of the package substrate.

3. The display device according to claim 1, wherein a first bottom surface of the first anchor has a different shape than a shape of a second bottom surface of the second anchor.

4. The display device according to claim 1, wherein the first to fourth anchors comprise a material that is cured and becomes conductive when subjected to heat and external force.

5. The display device according to claim 1, further comprising:
a first bonding material disposed between the first connection electrode and the first anchor, the first bonding material having conductivity and securing the first anchor to the first connection electrode;
a second bonding material disposed between the second connection electrode and the second anchor, the second bonding material having conductivity and securing the second anchor to the second connection electrode;
a third bonding material disposed between the third connection electrode and the third anchor, the third bonding material having conductivity and securing the third anchor to the third connection electrode; and
a fourth bonding material disposed between the fourth connection electrode and the fourth anchor, the fourth bonding material having conductivity and securing the fourth anchor to the fourth connection electrode.

6. The display device according to claim 1, further comprising:
a first conductive thin film disposed below the first anchor and having conductivity;
a second conductive thin film disposed below the second anchor and having conductivity;
a third conductive thin film disposed below the third anchor and having conductivity; and
a fourth conductive thin film disposed below the fourth anchor and having conductivity.

7. The display device according to claim 6, wherein the first to fourth conductive thin films comprise at least one material selected from carbon black, graphene, and silver nanowires.

8. The display device according to claim 1, wherein at least one of the first anchor, the second anchor, the third anchor and the fourth anchor comprises nanoconductive balls, and
wherein the nanoconductive balls are conductive and broken upon receiving external force.

9. The display device according to claim 1,
wherein the first anchor comprises a first anchor electrode post including a first metal material, and a first anchor electrode disposed on the first anchor electrode post and including a second metal material,
wherein the second anchor comprises a second anchor electrode post including the first metal material, and a second anchor electrode disposed on the second anchor electrode post and including the second metal material,
wherein the third anchor comprises a third anchor electrode post including the first metal material, and a third anchor electrode disposed on the third anchor electrode post and including the second metal material, and
wherein the fourth anchor comprises a fourth anchor electrode post including the first metal material, and a fourth anchor electrode disposed on the fourth anchor electrode post and including the second metal material.

10. The display device according to claim 9, wherein the first metal material is different from the second metal material.

11. The display device according to claim 9, further comprising:
a first conductive thin film disposed below the first anchor electrode post and having conductivity;
a second conductive thin film disposed below the second anchor electrode post and having conductivity;
a third conductive thin film disposed below the third anchor electrode post and having conductivity; and
a fourth conductive thin film disposed below the fourth anchor electrode post and having conductivity.

12. The display device according to claim 11, wherein a diameter or width of the first to fourth conductive thin films is smaller than a diameter or width of the first to fourth anchor electrode posts, respectively.

13. The display device according to claim 1, wherein the package substrate comprises at least one material selected from glass, a polymer-based material, and a silicon-based material.

14. The display device according to claim 1, wherein the first to fourth anchors comprise a conductive material, and the conductive material comprises at least one material selected from metal, a polymer-based material, and a ceramic material.

15. A light-emitting device package comprising:
a package substrate;
a first light-emitting device disposed on the package substrate, the first light-emitting device comprising a first light-emitting layer, a first electrode electrically connected to the first light-emitting layer, and a second electrode electrically connected to the first light-emitting layer;
a second light-emitting device disposed on the package substrate, the second light-emitting device comprising a second light-emitting layer, a third electrode electrically connected to the second light-emitting layer, and a fourth electrode electrically connected to the second light-emitting layer;
a first anchor electrically connected to the first electrode, the first anchor overlapping with the first electrode and penetrating through the package substrate; and
a second anchor electrically connected to the third electrode, the second anchor overlapping with the third electrode and penetrating through the package substrate.

16. The light-emitting device package according to claim 15, wherein a first bottom surface of the first anchor is positioned farther from the first light-emitting device than a bottom surface of the package substrate.

17. The light-emitting device package according to claim 15, wherein a first bottom surface of the first anchor has a different shape than a shape of a second bottom surface of the second anchor.

18. The light-emitting device package according to claim 15, further comprising:
a third anchor electrically connected to the second electrode, the third anchor overlapping with the second electrode and penetrating through the package substrate; and
a fourth anchor electrically connected to the fourth electrode, the fourth anchor overlapping with the fourth electrode and penetrating through the package substrate.

19. A method of manufacturing a light-emitting device package, the method comprising:
filling a conductive paste into a plurality of anchor holes of a package substrate;
placing a plurality of light-emitting devices on the conductive paste;
applying heat and external force to the plurality of light-emitting devices, thereby converting the conductive paste into a plurality of anchor posts; and
supplying power to the plurality of anchor posts through probe electrodes on a wafer substrate and inspecting whether the plurality of light-emitting devices emit light.

20. The method of manufacturing the light-emitting device package according to claim 19, further comprising:
a package picking step in which a stamp moves the plurality of light-emitting devices away from the wafer substrate, and the plurality of anchor posts are separated into a plurality of anchors and a plurality of wafer anchors.

21. The method of manufacturing the light-emitting device package according to claim 20, further comprising:
a package placing step in which the light-emitting device package, including the package substrate, the plurality of light-emitting devices on the package substrate, and the plurality of anchors overlapping the plurality of light-emitting devices, comes into contact with a bonding material on a lower substrate.
